(19) United States
(12) Patent Application Publication
(10) Pub. No.: US 2005/0054187 A1
(43) Pub. Date: Mar. 10, 2005

(54) Method for forming ball pads of BGA substrate

(75) Inventors: Yi-Chuan Ding, Kaohsiung (TW); Shun-Fu Ko, Kaohsiung (TW)

Correspondence Address: TROXELL LAW OFFICE PLLC, 5205 LEESBURG PIKE, SUITE 1404, FALLS CHURCH, VA, 22041, US

(73) Assignee: Advanced Semiconductor Engineering, Inc.

(21) Appl. No.: 10/933,350

(22) Filed: Sep. 3, 2004

(30) Foreign Application Priority Data
Sep. 5, 2003 (TW) 092124680

(51) Int. Cl. H01L 21/44; H01L 21/50; H01L 21/48; H01L 23/52

(52) U.S. Cl. 438/612; 438/106; 257/737; 257/780

(57) ABSTRACT

A method for forming ball pads of a BGA substrate is disclosed. A substrate is provided with a plurality of pad terminals on its surface. A solder mask is formed on the surface and has a plurality of openings to expose the pad terminals. A metal layer for redefining ball pads is formed on the solder mask. An etching mask is formed on the metal layer, the etching mask has a plurality of covering portions which are aligned with the pad terminals and larger than the openings of the solder mask. The metal layer is etched to form a plurality of redefined ball pads under the etching mask. The redefined ball pads cover the pad terminals of the substrate and extend around the openings of the solder mask so that solder balls can be jointed with the redefined ball pads to avoid contacting the solder mask and the pad terminals by redefinition of bonding area of solder balls.

### FIELD OF THE INVENTION

The present invention relates to a method for fabricating a BGA (ball grid array) substrate, more particularly, to a method for forming ball pads of a BGA substrate.

### BACKGROUND OF THE INVENTION

Conventionally, a ball grid array (BGA) substrate provides a chip carrier for BGA package. The BGA substrate includes a plurality of ball pads which are made by laminating a copper foil and then etching the copper foil to form the ball pads. The ball pads are configured for solder ball placement to provide outer electrical connection of BGA packages. Normally, a solder mask is applied on the BGA substrate to cover the corresponding circuits and expose the ball pads. The formation of the solder mask is a final step after the fabrication of the ball pads. According to the design of the openings of the solder mask, the ball pads can be classified into Non Solder Mask Defined (NSMD) pads and Solder Mask Defined (SMD) pads. On one hand, the NSMD ball pads are smaller than the solder mask openings on the NSMD ball pads so that the solder mask openings expose upper surfaces and sides of the NSMD ball pads, the exposed areas of the NSMD ball pads are not defined by the openings of the solder mask. Therefore, ball pads can provide a smaller contact area for solder ball placement when the solder mask openings are in the same dimension so as to place high-density wiring on the substrate. However, the bonding strength from NSMD ball pads to the substrate and solder balls are poor. On the other hand, the SMD ball pads are larger than the solder mask openings on the SMD pads so that the exposed area of the SMD ball pads is defined by the openings of the solder mask. Therefore, the bonding strength from the SMD ball pads to the substrate is better. However, solder balls contact the solder mask openings on the SMD ball pads, the bonding strength from the SMD ball pads to solder balls is poor. Moreover, the SMD ball pads occupy a larger area of the ball-placement surface of the substrate, the wirings cannot be formed in high density.

Please refer to FIG. 6, a conventional BGA package mainly includes a BGA substrate 110 with a plurality of ball pads 113, a chip 130 and a molding compound 140. The substrate 110 has a plurality of connecting pads 114 on the die-attach surface 112, and the ball pads 113 are formed on the ball-placement surface 111 of the substrate 110. Solder mask 120 are coated on the die-attach surface 112 and the ball-placement surface 111 respectively. The ball pads 113 are larger than openings 121 of the solder mask 120 to be SMD type. The chip 130 is attached to the die-attach surface 112 of the substrate 110. A plurality of bonding wires 132 connect the bonding pads 131 of the chip 130 and the connecting pads 114 of the substrate 110. Then the molding compound 140 is provided to seal the chip 130 and the bonding wires 132. A plurality of solder balls 150 are placed on the SMD ball pads 113. Wiring designing region of the ball-placement surface 111 for the wirings 115 becomes small due to the occupation of the SMD ball pads 113. Moreover, the bonding strength of the solder balls 150 to the SMD pads 113 becomes poor due to the contact between the solder balls 150 and the solder mask 120. The stress from the solder mask 120 will directly be focused on the solder balls 150, eventually, the reliability of the final BGA package will be poor.

As revealed in U.S. Pat. No. 6,396,707, NSMD type ball pads are formed on the ball-placement surface of a conventional BGA substrate and the openings of the solder mask on the ball-placement surface are slightly larger than the NSMD ball pads. However, the solder balls still make contact with the solder mask, which will not improve the reliability of the solder balls. Whatever shape the ball pads under the solder mask become, the reliability of the solder balls cannot be improved. Solder balls may easily “drop off” from the substrate. Even increasing the openings of the solder mask, only the risk of wiring exposure and electrical short is increased. Furthermore, the wiring layout on the substrate will be more difficult to design.

### SUMMARY OF THE INVENTION

The main purpose of the present invention is to provide a method for forming ball pads of a BGA substrate. A substrate with a plurality of pad terminals is provided and a solder mask is coated on the substrate. After solder mask processing step, a metal layer for redefining ball pads is formed on the solder mask to cover the pad terminals, then an etching mask is formed on the metal layer. Using the etching mask, the metal layer is etched to form a plurality of redefined ball pads. Therefore, bonding area of solder balls is redefined for increasing the solder ball reliability.

The second purpose of the present invention is to provide a method for forming ball pads of a BGA substrate. A metal layer for redefining ball pads is coated on the solder mask of the substrate. The metal layer is etched under an etching mask to form a plurality of redefined ball pads. The etching mask is a dry film or a solder pattern to allow the redefined ball pads can cover the corresponding pad terminals and extend onto the solder mask around the corresponding openings. In assembling a semiconductor package, solder balls on the redefined ball pads will not contact the edge of openings of the solder mask to enhance the solder ball reliability.

In a preferred method according to the present invention, a plurality of redefined ball pads are formed on a solder mask to cover pad terminals of the substrate. Firstly a substrate is provided, which includes a plurality of pad terminals and a solder mask. The pad terminals may be SMD pads or NSMD pads. The solder mask has a plurality of openings to expose the pad terminals. A metal layer for redefining ball pads is formed on the solder mask and covers the pad terminals via the solder mask openings. An etching mask is formed on the metal layer. The etching mask has a plurality of covering portions which are aligned with the pad terminals and are larger than the openings of the solder mask. Thereafter, the metal layer is etched, a plurality of redefined ball pads are formed under the covering portions of the etching mask. The redefined ball pads cover the solder mask openings and bended to the pad terminals, preferably, the edge of the redefined ball pads will cover and extend to the edge of the solder mask.

### DESCRIPTION OF THE DRAWINGS

FIG. 1A to FIG. 1E are cross-sectional views showing a substrate during formation process of the ball pads in accordance with a first embodiment of the present invention.

FIG. 2 is an enlarged bottom view of the substrate showing redefined ball pads in accordance with the first embodiment of the present invention.

FIG. 3 is a cross-sectional view of a preferred BGA package using the substrate having the redefined ball pads in accordance with the first embodiment of the present invention.

FIG. 4A to FIG. 4D are cross-sectional views of a substrate during formation process of the ball pads in accordance with a second embodiment of the present invention.

FIG. 5 is an enlarged top view of the substrate with pad terminals in accordance with the second embodiment of the present invention.

FIG. 6 is a cross-sectional view of a conventional BGA package.

### DETAIL DESCRIPTION OF THE INVENTION

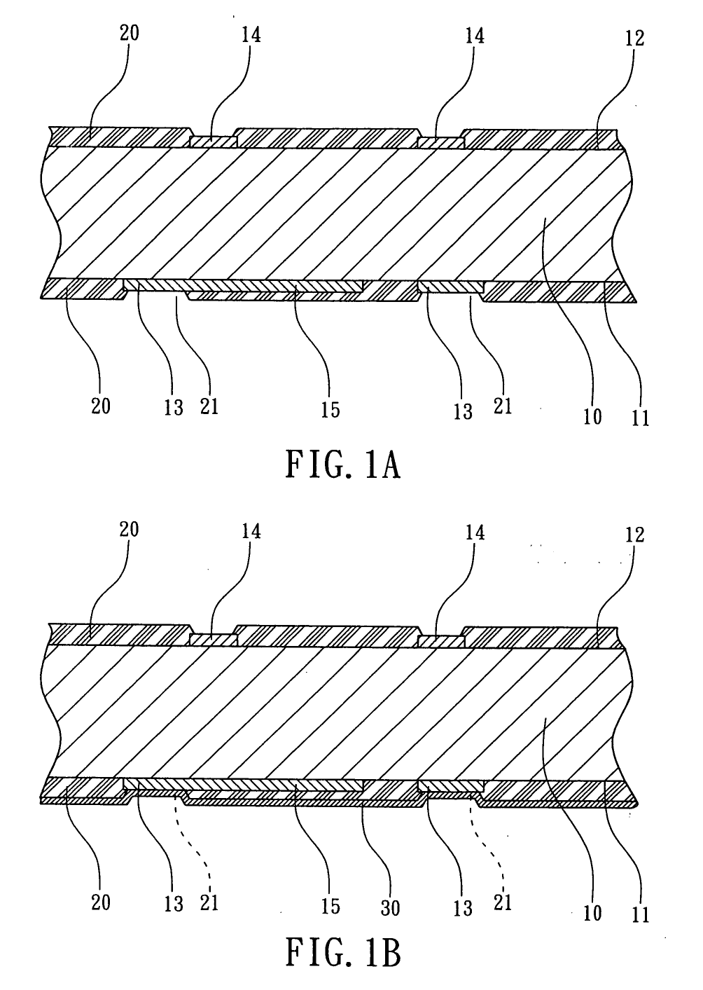

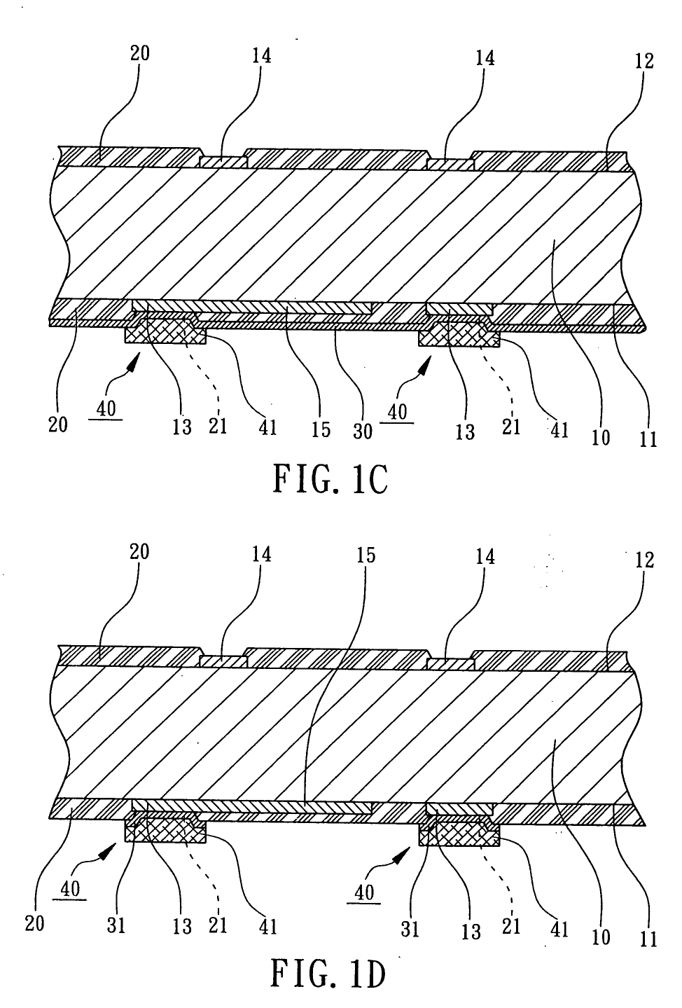

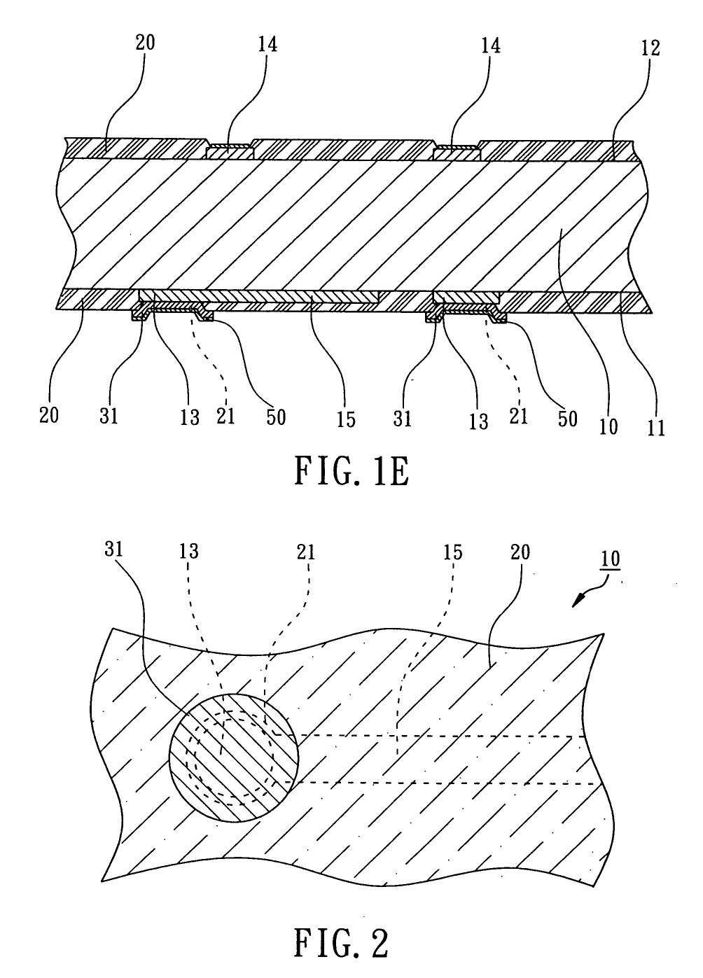

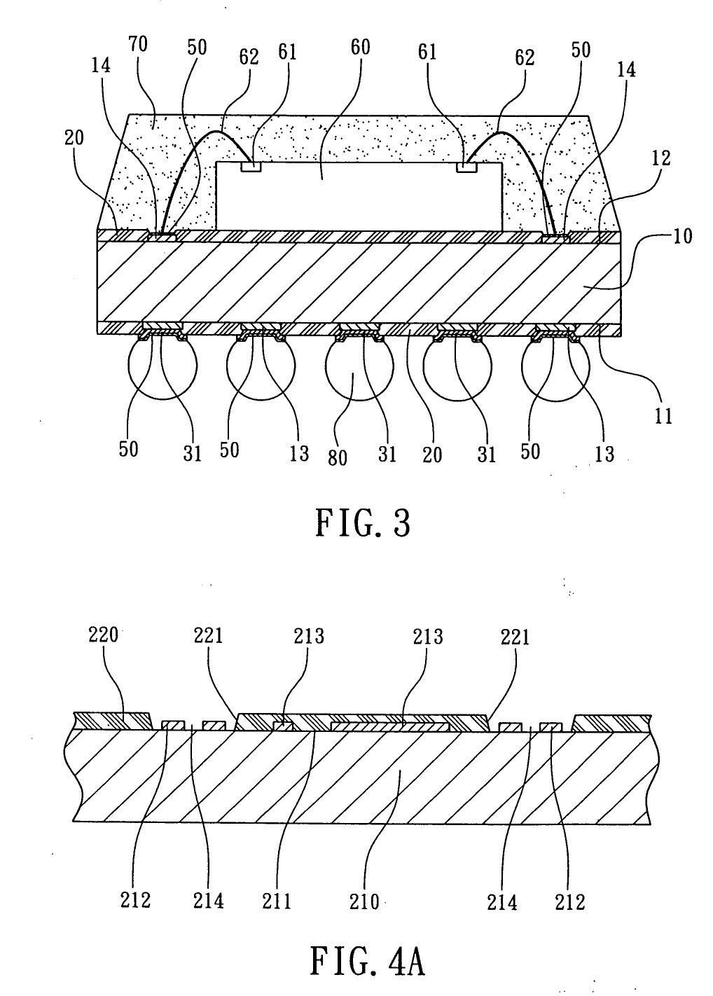

Please refer to the drawings attached, the present invention is described by means of an embodiment below. According to the present invention, the process for forming balls pads of a BGA substrate is disclosed. Referring to FIG. 1A, firstly, a substrate 10 is provided, which has a ball placement surface 11 and a die-attach surface 12 for attaching a semiconductor chip 60 (as shown in FIG. 3). A plurality of bonding pads 14 are formed on the die-attach surface 12 for electrical connection to the chip 60. A plurality of pad terminals 13 are formed on the surface 11. And solder masks 20 are formed on the surface 11 and the die-attach surface 12 respectively. As shown in FIG. 1A, the pad terminals 13 are fabricated from a same wiring layer including a plurality of metal wirings 15 on the surface 11 of the substrate 10. The pad terminals 13 can be in various shapes selected from square pads, or circular pads, even a trace terminal. As shown in FIG. 2, in this embodiment the pad terminals 13 are circular pads smaller than the openings 21 of the solder mask 20 as a SMD pads. Alternatively, the pad terminals 13 can be NSMD pads. The solder mask 20 has a plurality of openings 21 to expose the pad terminals 13. Thereafter, please refer to FIG. 1B, a metal layer 30 for redefining ball pads are formed on the solder mask 20 by means of electroless plating or sputtering. The metal layer 30 covers the pad terminals 13 via the openings 21 of the solder mask 20. The thickness of the metal layer 30 ranges between 3.0 μm and 5.0 μm. The metal layer 30 is etchable. In this embodiment, the metal layer 30 is made of the material containing copper.

Please refer to FIG. 1C, an etching mask 40 is formed on the metal layer 30. The etching mask 40 has a plurality of covering portions 41 which are aligned with the pad terminals 13. The covering portions 41 are larger than the opening 21 of the solder mask 20. In this embodiment, the etching mask 40 is a dry film. The dry film is attached on the metal layer 30 and is then exposed and developed to form the covering portions 41.

Thereafter, please refer to FIG. 1D, the metal layer 30 is etched under the protection of the covering portions 41 of the etching mask 40. A plurality of redefined ball pads 31 are formed under the covering portions 41 of the etching mask 40. The redefined ball pads 31 cover the pad terminals 13 and the edges of the openings 21 of the solder mask 20. The redefined ball pads 31 also extend onto the upper surface of the solder mask 20 around the corresponding openings 21 so that the solder balls 80 on the redefined ball pads 31 will not contact the edges of the openings 21 of the solder mask 20. According to the present embodiment, the thickness of the redefined ball pads 31 ranges between 3.0 μm and 5.0 μm which is much thinner and lighter than the conventional ball pads. Furthermore, please refer to FIG. 1E, preferably, a Ni/Au layer 50 is electroplated on the redefined ball pads 31 to prevent the oxidation of redefined ball pads 31 during packaging assembly processes and enhance the adhesion and reliability of solder balls 80.

Therefore, according to the method of forming ball pads of a BGA substrate of the present invention, the redefined ball pads 31 are formed on the solder mask 20 and extend through the openings 21. Moreover, the redefined ball pads 31 cover the pad terminals 13 and the edges of openings 21 of the solder mask 20. Therefore, the edges of openings 21 of the solder mask 20 are covered by the redefined ball pads 31 to avoid contacting the solder balls 80 as shown in FIG. 3.

A semiconductor package using the substrate 10 mentioned above comprises the substrate 10, a semiconductor chip 60, a molding compound 70 and a plurality of solder ball 80. The chip 60 is attached to the die-attach surface 12 of the substrate 10. A plurality of bonding wires 62 connect the bonding pads 61 of the chip 60 and the contact pads 14 of the substrate 10. The chip 60 and the bonding wires 62 are encapsulated by the molding compound 70. The surface 11 of the substrate 10 may be exposed out of the molding compound 70. Then a plurality of solder balls 80 are placed on the redefined ball pads 31 where the solder balls 80 do not directly contact with the edges of the opening 21 of the solder mask 20. Therefore, the reliability of the solder balls 80 can be enhanced. Moreover, the openings 21 of the solder mask 20 can be designed as small as possible in order to protect the high density metal circuits on the substrate 10.

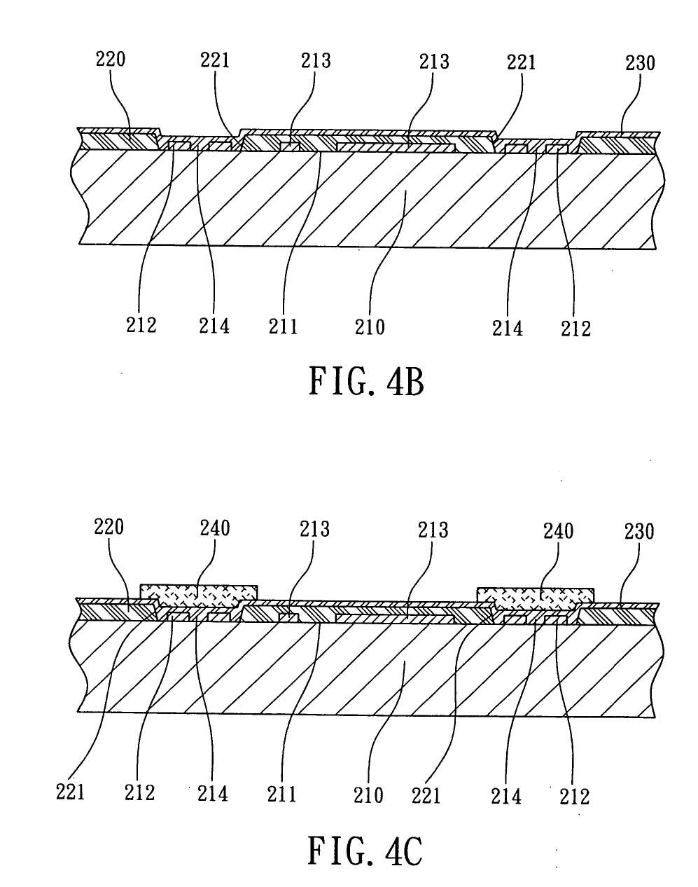

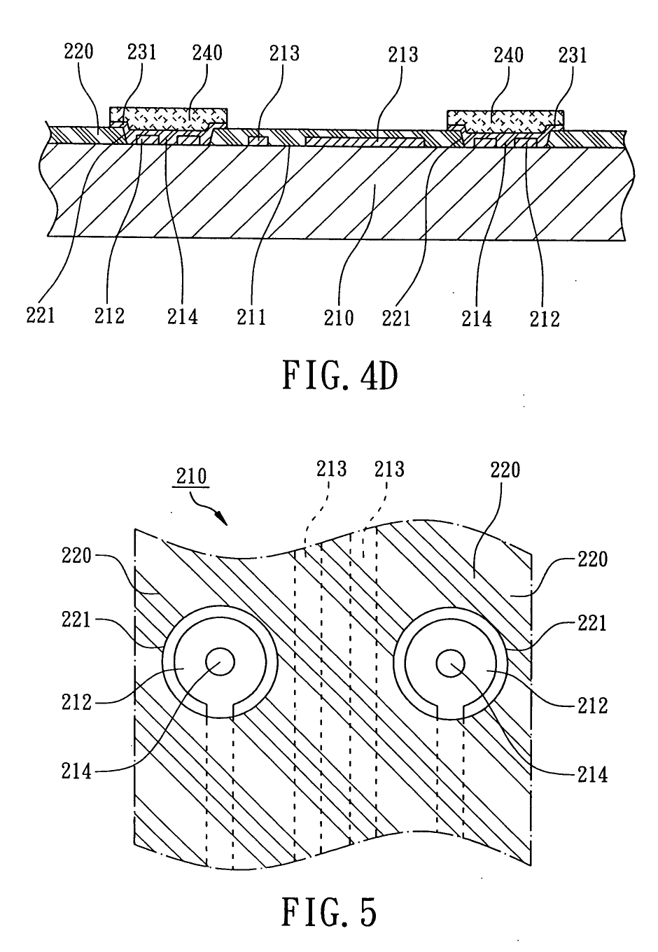

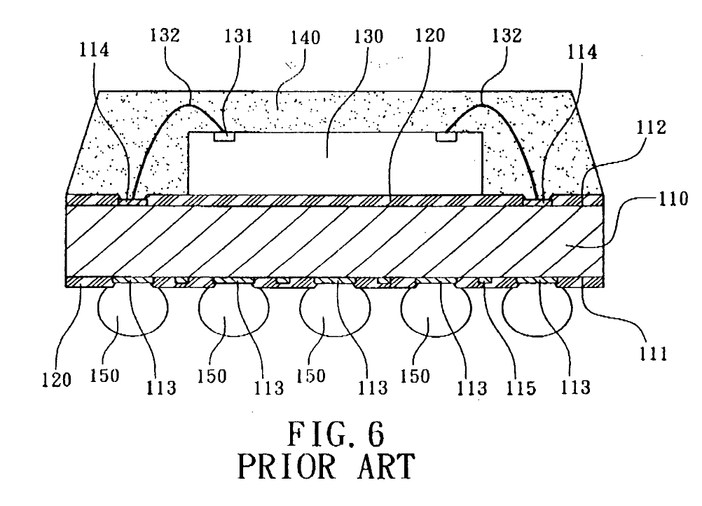

According to a second embodiment of the present invention, another preferred method for forming ball pads of a BGA substrate is shown in FIG. 4A˜4E. Firstly as shown in FIG. 4A, a substrate 210 is provided. The substrate 210 has a surface 211 for placing solder balls or bonding a flip chip. A plurality of pad terminals 212 and a plurality of metal wirings 213 are formed on the surface 211. Moreover, a solder mask 220 is formed on the surface 211 of the substrate 210, and the solder mask 220 has a plurality of openings 221 to expose the pad terminals 212. Preferably, as shown in FIG. 5, the pad terminals 212 are smaller than the openings 221 to be fully exposed out of the openings 221 of the solder mask 220 as NSMD pads. In this embodiment, each pad terminal 212 has a central hole 214 to increase the exposed area of the NSMD pad terminals 212.

FIG. 4B shows the substrate 210 after coating a metal layer 230. The metal layer 230 is formed on the solder mask 220 and covers the pad terminals 212 via the openings 221. Cu sputtering is a preferable method to form the metal layer 230. If necessary, a plasma treatment is performed prior to forming the metal layer 230 so as to roughen the surface of the solder mask 220.

FIG. 4C shows the substrate 210 after forming an etching mask 240. In this embodiment, the etching mask 240 is a solder pattern, such as 63 Sn/37 Pb or lead-free solder. The solder pattern 240 is formed on the metal layer 230 by means of stencil printing or screen printing a solder paste. The covering regions of the solder pattern 240 are aligned with the pad terminals 212 and larger than the openings 221 of the solder mask 220. After a slight reflowing, the solder pattern 240 can be bonded to the metal layer 230.

FIG. 4D shows the substrate 210 after passing through an etching step. The metal layer 230 is etched off by a wet etching process except for portions of the metal layer 230 under the solder pattern 240. Therefore a plurality of redefined ball pads 231 under the solder pattern 240 are formed from the metal layer 230. The solder pattern 240 on the redefined ball pads 231 is not necessary to be removed even in the packaging processes. In addition that the solder pattern 240 is very useful as an etching mask, the solder pattern 240 can be a protective layer and a wetting layer for the redefined ball pads 231.

The above description of embodiments of this invention is intended to be illustrative and not limiting. Other embodiments of this invention will be obvious to those skilled in the art in view of the above disclosure.

1. A method for forming ball pads of a BGA substrate, comprising:
providing a substrate, the substrate having a plurality of pad terminals and a solder mask on a surface, the solder mask having a plurality of openings to expose the pad terminals;
forming a metal layer on the solder mask, the metal layer covering the pad terminals via the openings;
forming an etching mask on the metal layer, the etching mask having a plurality of covering portions which are aligned with the pad terminals and are larger than the openings of the solder mask; and
etching the metal layer to form a plurality of redefined ball pads under the covering portions of the etching mask.

2. The method of claim 1, wherein the redefined ball pads extend onto the solder mask around the corresponding openings.

3. The method of claim 1, wherein the thickness of the redefined ball pads ranges between 3.0 and 5.0 μm.

4. The method of claim 1, wherein the metal layer is formed by electroless plating or sputtering.

5. The method of claim 1, wherein the redefined ball pads are made of the material containing copper.

6. The method of claim 1, wherein a Ni/Au layer is formed on the redefined ball pads.

7. The method of claim 1, wherein the etching mask is a dry film.

8. The method of claim 1, wherein the etching mask is a solder pattern.

9. The method of claim 8, wherein the solder pattern is formed on the metal layer by stencil printing or screen printing of a solder paste.

10. The method of claim 1, wherein the pad terminals are SMD (Solder Mask Defined) pads.

11. The method of claim 1, wherein the pad terminals are NSMD (Non-Solder Mask Defined) pads.

12. The method of claim 1, wherein each pad terminal has a central hole.

13. The method of claim 1, further comprising a plasma treatment on the solder mask.

14. A substrate for semiconductor package comprising:
a substrate having a surface;
a plurality of pad terminals are formed on the surface;
a solder mask formed on the surface, the solder mask having a plurality of openings to expose the pad terminals, and
a plurality of redefined ball pads covering the pad terminals via the openings, the redefined ball pads are larger than the openings of the solder mask.

15. The substrate of claim 14, wherein the redefined ball pads extend onto the solder mask around the corresponding openings

16. The substrate of claim 14, wherein the thickness of the redefined ball pads ranges between 3.0 μm and 5.0 μm.

17. The substrate of claim 14, wherein the redefined ball pads are made of the material containing copper.

18. The substrate of claim 14, further comprising a Ni/Au layer being formed on the redefined ball pads.

19. The substrate of claim 14, further comprising an etching mask being formed on the redefined ball pads.

20. The substrate of claim 14, wherein the etching mask is a solder pattern.

21. The substrate of claim 14, wherein the pad terminals are SMD (Solder Mask Defined) pads.

22. The substrate of claim 14, wherein the pad terminals are NSMD (Non-Solder Mask Defined) pads.

23. The substrate of claim 14, wherein each pad terminal has a central hole.
